(19) United States
(12) Patent Application Publication
(10) Pub. No.: US 2014/0035577 A1
(43) Pub. Date: Feb. 6, 2014

(54) MAGNETIC RESONANCE IMAGING COORDINATED WITH A PHYSIOLOGICAL CYCLE

(71) Applicant: SIEMENS AKTIENGSELLSCHAFT, Munich (DE)

(72) Inventors: Jan Ole BLUMHAGEN, Erlangen (DE); Matthias FENCHEL, Erlangen (DE); Ralf LADEBECK, Erlangen (DE)

(73) Assignee: SIEMENS AKTIENGSELLSCHAFT, Munich (DE)

(21) Appl. No.: 13/950,381

(22) Filed: Jul. 25, 2013

(30) Foreign Application Priority Data
Aug. 2, 2012 (DE) 102012213696.7

(51) Int. Cl. G01R 33/54

(52) U.S. Cl. CPC G01R 33/543
USPC 324/309; 324/318

(57) ABSTRACT

To carry out magnetic resonance (MR) tomography, a physiological parameter of an object to be examined is acquired as a function of time to detect a physiological cycle which repeats itself over time. First MR data is acquired for a first region, wherein all points of the first region are arranged in a region of a field of view of an MR system. Acquisition of the first MR data occurs selectively in first time intervals which are synchronized with the physiological cycle and are separated from each other by waiting intervals. Second MR data is acquired for a second region which adjoins the first region. Acquisition of the second MR data occurs in the waiting intervals between the first time intervals.

### PRIORITY STATEMENT

The present application hereby claims priority under 35 U.S.C. §119 to German patent application number DE 102012213696.7 filed Aug. 2, 2012, the entire contents of which are hereby incorporated herein by reference.

### FIELD

At least one embodiment of the invention generally relates to a magnetic resonance (MR) tomography method, to an MR system and/or to an MR-PET hybrid system. At least one embodiment of the invention relates in particular to methods and systems in which MR data acquisition is carried out so as to be coordinated with a physiological cycle, by way of example a cardiac or breathing cycle.

### BACKGROUND

MR tomography is used to a large extent in medical imaging. Various recording techniques are known in which information about an object to be examined is obtained by switching gradient fields, radiating excitation pulses and detecting the resulting magnetization. Spin echo or gradient echo techniques are examples of such recording techniques.

The images resulting from movement of sections of the object to be examined can have movement artifacts. These may be caused at least partially by physiological cycles of the object to be examined. Conventional breathing movements or the movement of the heart muscle in the thorax region by way of example can reduce the image quality, making reliable diagnosis difficult.

What is known as ECG triggering, respiration gating or a combination thereof may be used to increase the image quality. These techniques can be used to carry out data acquisition in such a way that movement is slight during data acquisition. A cardiac cycle or breathing cycle can be detected for this purpose. MR data acquisition can be synchronized with the physiological cycle. Trigger signals can be generated for this purpose, so measuring always starts and proceeds during an identical physiological phase. In particular MR data acquisition can occur in a rest phase in which organs or other sections to be mapped of the object being examined do no move much. In the case of gating, acquisition switches on during a certain time slot, for example if the movement is very slight, and then switches off again. Whereas ECG triggering by way of example is used primarily for cardio imaging, respiratory triggering or respiratory gating is also used for thorax or abdominal imaging to reduce movement artifacts.

Gating techniques and trigger techniques are also used in positron-emission tomography (PET), particularly if this is used to map tumors in moving organs. For reliable attenuation correction of the PET image in the case of combined MR-PET hybrid imaging it is desirable to carry out MR data acquisition, used for the attenuation correction, so as to be coordinated with the physiological cycle.

One drawback in conventional MR methods when using trigger or gating methods is that only some of the examination time is used for the actual measurement.

To reduce this drawback MR recording techniques may be used which allow fast data acquisition and which make good use of the time slot predefined by the physiological cycle. There is no MR data acquisition outside of this time slot, however, since during this phase the existing movement would greatly affect the image quality. Alternatively or additionally, breath-holding techniques may be used to freeze the movement during data acquisition. Breath-holding techniques reach their limits in the case of long measurements or patients who have problems holding their breath.

Techniques for MR imaging with which a region at the edge of a field of view of an MR system, which is located outside of a specification volume, may also be mapped are described in DE 10 2010 044 520 A1.

### SUMMARY

At least one embodiment of the invention is based on improved methods and devices for MR imaging in which MR data is acquired in a manner coordinated with a physiological cycle. At least one embodiment of the invention is in particular based on methods and devices in which the available measuring time can be optimally used.

Methods and devices with the features disclosed in the independent claims are provided. The dependent claims define embodiments.

According to embodiments of the invention, a waiting time outside of the usual time slot, which is defined as a function of the physiological cycle, is used for MR data acquisition at low-movement regions of the body. In embodiments there is a combination or interlacing of a first MR data acquisition of the high-movement regions within first time intervals, which may be gating-time slots, and a second MR data acquisition of the low-movement regions, which are carried out in waiting intervals between the gating time slots.

According to one aspect of an embodiment, a magnetic resonance (MR) tomography method is provided. A physiological parameter of an object to be examined is acquired as a function of time to detect a physiological cycle which repeats itself over time. First MR data is acquired for a first region, wherein all points of the first region are arranged in a predefined region of field of view of an MR system, in particular are arranged in a predefined environment of an isocenter of a basic field. The first MR data is acquired selectively in first time intervals which are synchronized with the physiological cycle and which are separated from each other by waiting intervals. Second MR data is acquired for a second region which is different from the first region. The second MR data is acquired in the waiting intervals between the first time intervals.

According to a further aspect an MR system is disclosed. The MR system comprises a device for generating a B0 field, i.e. the basic field. The MR system comprises an acquisition device for acquiring MR data and a controller for controlling the MR system. The controller has an interface for receiving a signal which depends on a physiological parameter of an object to be examined. The controller is set up to detect a physiological cycle which repeats itself over time as a function of the signal received at the interface. The controller is set up to control the acquisition device for acquiring first MR data for a first region, wherein all points of the first region are arranged in a predefined region of a field of view of the MR system, in particular in a predefined environment of an isocenter of the basic field. The controller is set up to control the acquisition device in such a way that the first MR data is selectively acquired in first time intervals which are synchronized with the physiological cycle and which are separated from each other by waiting intervals. The controller is set up to control the acquisition device for acquisition of second MR data for a second region, which adjoins the first region in such a way that the second MR data is acquired in the waiting intervals between the first time intervals.

Designs of the MR system according to embodiments and the effects achieved thereby in each case correspond to the designs of the method. The controller of the MR system can automatically induce corresponding control of the MR system to bring about automatic execution of the method steps.

The MR system can be set up to carry out the method according to an aspect or example embodiment.

According to a further aspect of an embodiment, an MR-PET hybrid system is disclosed. The MR-PET hybrid system comprises an MR system according to an aspect or example embodiment. The MR-PET hybrid system comprises a positron emission tomograph which has a detector for acquiring PET data. The positron emission tomograph comprises a processing device which is coupled to the MR system and is set up to determine an attenuation map for the PET data as a function of the first MR data and second MR data acquired using the MR system.

Example embodiments of the invention are not limited to application in MR-PET hybrid systems but may generally be used in methods and systems for MR imaging in which movement artifacts are reduced in that MR data of moving sections of the object to be examined is acquired so as to be synchronized with a physiological cycle.

### BRIEF DESCRIPTION OF THE DRAWINGS

The above-described properties, features and advantages of this invention and the manner in which they are attained will become clearer and more comprehensible in connection with the following description of the example embodiments which are explained in more detail in connection with the drawings, in which:

FIG. 1 shows an MR-PET hybrid system according to an example embodiment.

FIG. 2 illustrates different regions of a field of view of an MR system of the system in FIG. 1.

FIG. 3 illustrates MR data acquisition in methods and devices according to an example embodiment.

FIG. 4 illustrates MR data for different sections of an object to be examined, for which data is acquired using methods and devices according to example embodiments.

FIG. 5 illustrates MR data acquisition in methods and devices according to an example embodiment.

FIG. 6 is a flow diagram of a method according to an example embodiment.

FIG. 7 is a flow diagram of a method according to a further example embodiment.

FIG. 8 illustrates an MR image which has been obtained with methods and devices according to example embodiments.

FIG. 9 illustrates an MR image which has been obtained with a conventional method.

FIG. 10 illustrates the generation of an attenuation map from first and second MR data.

FIG. 11 and FIG. 12 illustrate image data which is obtained in methods and devices according to example embodiments.

FIG. 13 illustrates a sequence of high frequency pulses which can be used for preparing magnetization in methods and devices for a transition between recording techniques.

In the figures identical or corresponding reference numerals denote identical or corresponding elements, devices or method steps.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

According to one aspect of an embodiment, a magnetic resonance (MR) tomography method is provided. A physiological parameter of an object to be examined is acquired as a function of time to detect a physiological cycle which repeats itself over time. First MR data is acquired for a first region, wherein all points of the first region are arranged in a predefined region of field of view of an MR system, in particular are arranged in a predefined environment of an isocenter of a basic field. The first MR data is acquired selectively in first time intervals which are synchronized with the physiological cycle and which are separated from each other by waiting intervals. Second MR data is acquired for a second region which is different from the first region. The second MR data is acquired in the waiting intervals between the first time intervals.

Different periods of time are used in the method to map different regions of the object to be examined. The first region, which may be arranged in a specification region of the MR system, is detected in first time slots which are defined so as to be coordinated with the physiological cycle. The waiting intervals between the first time slots are used to acquire image data for the second region. This may involve a scan for sections of the object to be examined which do not change their position, or change it only slightly, during the physiological cycle. The available measuring time is better utilized by acquisition of the second data during the waiting intervals.

The second region, for which second MR data is acquired, can adjoin the first region. The second region can surround the first region, by way of example in the manner of a ring. The second region and the first region may also overlap.

The specification region of the field of view, for which the first MR data can be acquired in the first time intervals, can be the region of the field of view in which an inhomogeneity in the basic field is smaller than a predefined threshold value. A region of this kind is often called the specification volume of the MR system. The second region may be partially or completely located outside of the specification volume.

A relative position between the object to be examined and the MR system can be adjusted in such a way that sections of the object to be examined, which move during the physiological cycle, are arranged in the first region. This ensures that movement artifacts stay small. MR data for the sections moving so as to be coordinated with the physiological cycle is acquired in the first time intervals in which the movement is small, i.e. in rest phases of the cycle.

The second MR data can map low-movement sections of the object to be examined. The second MR data can map sections of the object to be examined whose movement amplitude during the physiological cycle is less than a threshold value. The second MR data can in particular map arms of the object to be examined. Position and contour of the arms can be significant by way of example for an MR-based determination of an attenuation correction. The low-movement sections of the object to be examined may be positioned at an edge of the field of view of the MR system. The low-movement sections of the object to be examined may be positioned at least partially outside of the specification volume.

Acquisition of the second MR data can include measures to reduce distortions. For this purpose a gradient strength of at least one gradient field can be adjusted as a function of an inhomogeneity in the basic field and a non-linearity of the gradient field of the MR system at a certain location, for which distortion-reduced data acquisition should occur. Alternatively or additionally, a distortion correction for the second MR data may also be made by a computer.

The method can be carried out using an MR positron emission tomography (PET) hybrid system. An attenuation map for a PET image can be determined based on the first MR data and the second MR data. The attenuation map can be used for an attenuation correction of PET data. The attenuation map can be used to generate an attenuation-corrected PET image.

Determination of the attenuation map can include an absorption parameter being determined for the photons detected during PET for a plurality of voxels which are arranged in the first region, based on the first MR data in each case. An absorption parameter for the photons detected during PET can be determined for a plurality of voxels which are arranged in the second region, based on the second MR data in each case.

The first MR data can be acquired using a first MR acquisition technique. This can in particular take into account the fact that a fast first acquisition technique should be used for MR data acquisition in the first region, whereas a second acquisition technique, which allows a correction of an inhomogeneity in the basic field and/or a non-linearity of a gradient field in the second region, can be used for MR data acquisition in the second region. The second MR acquisition technique is different from the first MR acquisition technique in this case.

The second MR acquisition technique can be an MR acquisition technique which allows compensation of dephasing effects. In particular the second MR acquisition technique can be a spin echo acquisition technique. Dephasing effects, which are caused by an inhomogeneity in the basic field at the edge of the field of view of the MR system, can be compensated as a result.

The first MR acquisition technique can include generation of a gradient echo sequence. The second MR acquisition technique can include generation of a spin echo sequence. The first acquisition technique can be non-layer-selective. The second acquisition technique can be layer-selective. Such an embodiment means fast data acquisition for the section of the object to be examined, which moves with the physiological cycle, can be combined with data acquisition of low-movement sections which are positioned in an edge region of the field of view.

If the first and second acquisition techniques are different a transition sequence which is coordinated with the physiological cycle can be generated to prepare the object to be examined for data acquisition using the first MR acquisition technique. Acquisition of the second MR data can be terminated even before the end of a waiting interval in order to carry out the transition sequence. A time at which the transition sequence is initiated can be defined as a function of the physiological cycle. A time at which acquisition of the second MR data is terminated during the waiting interval in each case can automatically be defined as a function of the duration of the physiological cycle and as a function of a period which is required for the first acquisition technique for preparing magnetization.

The first acquisition technique can be based on a fast gradient echo sequence in the state of equilibrium of transversal magnetization (by way of example a “Steady State Free Precession”, SSFP sequence). To prepare the magnetization a sequence of high frequency pulses can be generated, and this leads by way of example to the magnetization vector oscillating between angles of +α/2 and −α/2 about the z axis. To prepare magnetization as quickly as possible a sequence of high frequency pulses can be generated by way of example in which firstly a flip angle of +α/2 is radiated as the first pulse and then high frequency pulses are alternately radiated for flip angles of −α and +α. The interval between the first (+α/2) high frequency pulse and the subsequent high frequency pulse with a flip angle of −α can be half as large as the interval between successive high frequency pulses respectively for tilting about a flip angle of ±α.

The second region of the object to be examined, for which MR data is acquired during the waiting intervals, can be arranged at an edge of the field of view of the MR system. The second region can be located at least partially outside of the specification volume, so the inhomogeneity in the basic field and the non-linearity of the gradient field can be greater there than a threshold value.

The second MR data can be acquired in second time intervals respectively which are included in the waiting intervals. The duration of the second time intervals can be chosen as a function of the duration of the physiological cycle. As a result the duration of the second time intervals can be matched to the first time intervals in which the first data can be acquired, and, if necessary, the duration of a transition sequence.

The physiological cycle can be a cardiac cycle or a breathing cycle.

According to a further aspect an MR system is disclosed. The MR system comprises a device for generating a B0 field, i.e. the basic field. The MR system comprises an acquisition device for acquiring MR data and a controller for controlling the MR system. The controller has an interface for receiving a signal which depends on a physiological parameter of an object to be examined. The controller is set up to detect a physiological cycle which repeats itself over time as a function of the signal received at the interface. The controller is set up to control the acquisition device for acquiring first MR data for a first region, wherein all points of the first region are arranged in a predefined region of a field of view of the MR system, in particular in a predefined environment of an isocenter of the basic field. The controller is set up to control the acquisition device in such a way that the first MR data is selectively acquired in first time intervals which are synchronized with the physiological cycle and which are separated from each other by waiting intervals. The controller is set up to control the acquisition device for acquisition of second MR data for a second region, which adjoins the first region in such a way that the second MR data is acquired in the waiting intervals between the first time intervals.

Designs of the MR system according to embodiments and the effects achieved thereby in each case correspond to the designs of the method. The controller of the MR system can automatically induce corresponding control of the MR system to bring about automatic execution of the method steps.

The MR system can be set up to carry out the method according to an aspect or example embodiment.

According to a further aspect of an embodiment, an MR-PET hybrid system is disclosed. The MR-PET hybrid system comprises an MR system according to an aspect or example embodiment. The MR-PET hybrid system comprises a positron emission tomograph which has a detector for acquiring PET data. The positron emission tomograph comprises a processing device which is coupled to the MR system and is set up to determine an attenuation map for the PET data as a function of the first MR data and second MR data acquired using the MR system.

The techniques according to example embodiments in which MR data for low-movement sections of the object to be examined is acquired in the waiting intervals, in which by way of example a cardiac or breathing cycle would lead to movement artifacts in other sections of the object to be examined, can therefore be used in particular in MR-PET hybrid systems. For such systems it is desirable to also be able to take into account the attenuation of the acquired PET signal caused by the contour and the cross-section of arms. The techniques according to example embodiments allow imaging for the arms to be carried out in the waiting intervals using the second MR data. This data can then be combined with the first MR data, by way of example to calculate an attenuation map of the object to be examined.

Example embodiments of the invention are not limited to application in MR-PET hybrid systems but may generally be used in methods and systems for MR imaging in which movement artifacts are reduced in that MR data of moving sections of the object to be examined is acquired so as to be synchronized with a physiological cycle.

The features of the example embodiments may be combined with each other provided this is not expressly ruled out in the following description. While some example embodiments are described in the context of specific applications, by way of example in the context of an MR-PET hybrid system, the example embodiments are not limited to such applications.

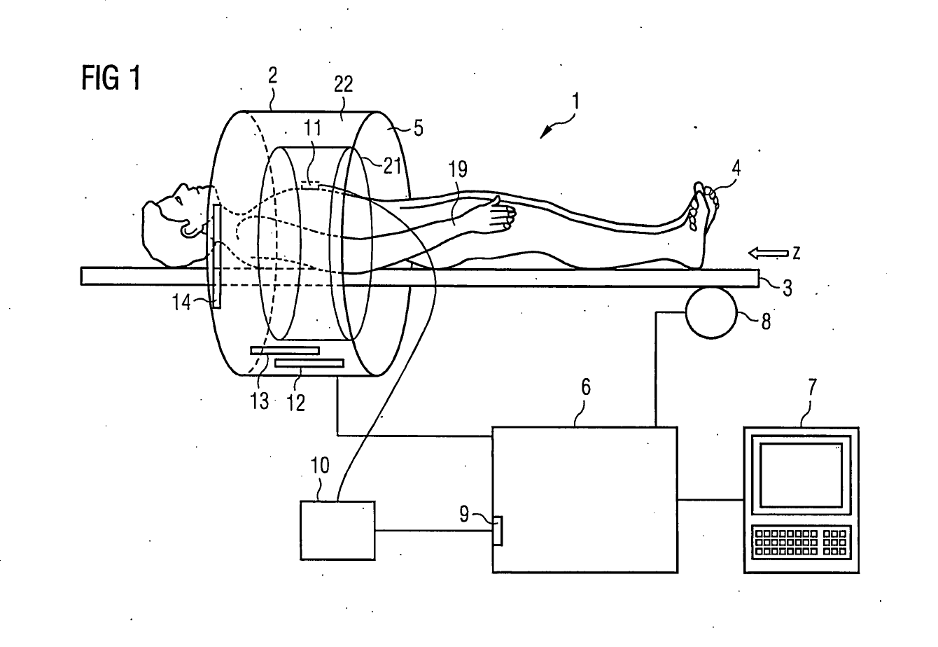

FIG. 1 shows a schematic diagram of an MR-PET hybrid system 1. The MR-PET hybrid system 1 comprises an MR system with a tomograph 2, examination table 3 for an object to be examined 4, by way of example a patient 4 who can be moved on the examination table 3 through an opening 5 in the tomograph 2, a controller 6, evaluation device 7 and a drive unit 8. The controller 6 and evaluation device 7 can include one or more processor(s). The controller 6 and evaluation device 7 can be designed as computers. The controller 6 controls the tomograph 2 and receives signals from the tomograph which are recorded by way of example by MR pick-up coils 12.

A PET detector 13 may be provided to acquire PET data. Data acquisition of the PET data and evaluation of the PET data can likewise occur by way of the controller 6 and the evaluation device 7. Alternatively, a separate controller and/or a separate evaluation computer may be provided for acquisition and processing of the PET data. For acquisition of the PET data the controller would in this case operate so as to be coordinated with controller 6 for MR data acquisition, to acquire both MR data and PET data as a function of a physiological cycle of the object to be examined.

To generate a basic magnetic field B0 the tomograph 2 has a basic field magnet 14 (shown only schematically). The tomograph 2 has a gradient field system for generating gradient fields. The tomograph 2 has one or more high frequency antennae for generating high frequency signals. The drive unit 8 can be automatically controlled by the controller 6 to move the examination table 3 along a direction Z, together with the object to be examined 4, through the opening 5 of the tomograph. The controller 6 and the evaluation device 7 can by way of example be a computer system with a screen, keyboard and a data carrier on which electronically readable control information is stored which is configured in such a way that when using the data carrier in the evaluation device 7 and controller 6 execution of the method described in detail below is induced.

The MR-PET hybrid system 1 is designed in such a way that MR data acquisition is carried out so as to be coordinated with a physiological cycle of the object to be examined 4. The physiological cycle can by way of example be a cardiac cycle or a breathing cycle. To carry out MR data acquisition so as to be coordinated with the physiological cycle the MR-PET hybrid system 1 can include a device for monitoring a physiological parameter of the object to be examined 4. This device can detect an EKG signal and/or breathing of the object to be examined and/or other physiological parameter. The device can include a sensor 11 for acquiring the physiological parameter. The device can include an evaluation unit 10 which evaluates the physiological signal detected by the sensor 11. By way of example the evaluation unit 10 can evaluate the physiological parameter monitored as a function of time and generate trigger signals or gating signals as a function thereof. The controller 6 can include a corresponding interface 9 for receiving signals from the evaluation unit 10. In further embodiments the function of the evaluation unit 10 can be integrated in the controller 6, so the controller 6 can receive signals directly from the sensor 11 at the interface 9.

During operation the controller 6 controls the tomograph 2 as a function of the signal received at the interface 9. The controller 6 controls the tomograph 2 such that for a first physical region first MR data is acquired as a function of and so as to be coordinated in terms of time with the physiological cycle. This acquisition of the first MR data can be a triggered or gated data acquisition. The first region for which the first MR data is acquired in this way is located in such a way that the sections of the object to be examined which change significantly with the physiological cycle are mapped with the first MR data. This triggered or gated data acquisition can map a large part of a cross-section through the object to be examined 4 and will hereinafter also be called “primary MR data acquisition”. To keep movement artifacts small the controller 6 controls the tomograph 2 in such a way that the acquisition of the first MR data is synchronized with the physiological cycle. In other words, the first MR data is in each case acquired in a predefined time relationship with the physiological cycle. Acquisition of the first MR data is performed in a plurality of first time intervals which may by way of example be gating time slots or time intervals defined by trigger signals. The first time intervals are each separated from each other by waiting intervals. The first time intervals can be chosen such that they match rest phases of the physiological cycle in which the mapped sections of the object to be examined are at relative rest.

The controller 6 continues to control the tomograph 2 such that in the waiting intervals between these rest phases second MR data is acquired for a second physical region. The second region is adjacent to the first region and can in particular include those sections of the object to be examined 4 which do not move during the physiological cycle, or move only slightly. One example of such sections of the object to be examined 4 is arms 19 of the object to be examined. Acquisition of the second MR data is also called “secondary data acquisition” here.

The controller 6 therefore controls the tomograph 2 in such a way that acquisition of first MR data, with which high-movement sections of the object to be examined 4 are mapped and which are selectively carried out only in predefined first time intervals as a function of the physiological cycle, is combined with acquisition of second MR data. The latter maps low-movement sections of the object to be examined 4 and is acquired during the waiting intervals between the rest phases of the physiological cycle, i.e. between the first time intervals. The two data acquisitions are interlaced time-wise. Second MR data is respectively acquired between two first time intervals in which the first MR data is acquired.

The secondary MR data acquisition of the arms 19 or other sections of the object to be examined 4, which conventionally do not exhibit any movement, is carried out during the high-movement respiratory or cardiac phase which previously has been unused. A total required measuring time can therefore be reduced and/or an available measuring time can be better utilized.

Interlacing of the primary MR data acquisition for high-movement sections in the first region and secondary MR data acquisition for low-movement sections in the second region can therefore be carried out in such a way that the low-movement sections are positioned outside of the specification volume of the MR system. In this case methods of distortion correction can be used when acquiring second MR data in order to be able to generate MR image data with reduced distortion in an edge region of the field of view and outside of the specification volume as well. The field of view of the MR system in the MR-PET hybrid system 1 can include a specification volume 21 by way of example in which the inhomogeneity in the basic field is less than a predefined threshold value. As a result it can be guaranteed that distortions are small for data acquisition in the specification volume 21. The specification volume typically includes an isocenter of the basic field and extends up to a predetermined spacing therefrom. The specification volume is sometimes also called a “specified field of view” or “specified FoV”. An edge region 22 of the field of view adjoins the specification volume 21 and can surround it. The controller 6 can control the tomograph 2 in such a way that high-movement sections of the object to be examined are positioned in the specification volume 21 and only low-movement sections of the object to be examined, whose position does not change during the physiological cycle, or changes only slightly, are positioned in the edge region 22.

A corresponding relative position between the object to be examined 4 and the tomograph 2 such that only low-movement sections are arranged in the edge region 22 of the field of view, can typically be easily accomplished. In particular the specification volume 21 typically has a diameter of about 50 cm, so the relevant high-movement sections can be positioned inside the specification volume 21.

It should be noted that during the first time intervals, i.e. during primary data acquisition, MR data may also be acquired for the edge region 22 of the field of view. This MR data for the edge region 22 acquired during primary data acquisition can however be discarded during further processing to keep distortion corrections low. Alternatively, a weighted overlaying comprising the second MR data and MR data acquired during primary data acquisition can be formed for the edge region 22. Similarly, during the waiting intervals, i.e. during secondary data acquisition, MR data may also be acquired for the specification volume 21 of the field of view. This MR data for the specification volume 21, acquired during secondary data acquisition, can however be discarded during further processing to keep movement artifacts low. Alternatively, a weighted overlaying comprising the first MR data and MR data acquired during secondary data acquisition can be formed for the specification volume 21.

The first MR data and the second MR data can be processed further by the evaluation device 7. By way of example, the first MR data and the second MR data can be combined to form an MR image. The corresponding pixels can be taken from the first MR data for high-movement sections of the object to be examined and from the second MR data for low-movement sections of the object to be examined.

The first MR data and the second MR data can be processed to generate an attenuation map for a PET scan. The attenuation map can include spatially resolved information about an absorption coefficient for the photons which are generated during the PET by annihilation. Information about the position and large different types of tissue can be determined from the first MR data and the second MR data, by way of example by segmenting. An attenuation map can automatically be calculated by the evaluation device 7 from this information, by way of example by using information, calculated in advance, about a tissue type-dependent absorption coefficient. The attenuation map can be used for attenuation correction of PET data.

Whereas an MR-PET hybrid system 1 has been described with reference to FIG. 1, in further example embodiments of the invention the method described in more detail below can also be designed with an MR system which is not configured as an MR-PET hybrid system. The embodiment of such an MR system matches the embodiment schematically illustrated in FIG. 1, wherein no PET detector 13 has to be provided, however.

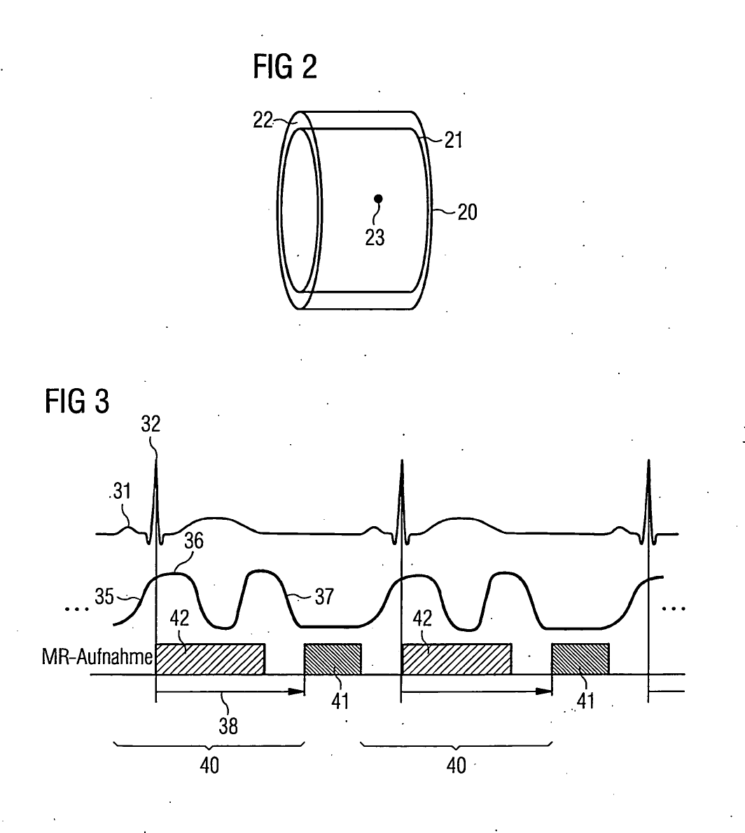

FIG. 2 illustrates different regions of a field of view 20 of an MR system according to an example embodiment. In a specification volume 21 the inhomogeneity in the basic field is small and distortions are small. In an edge region 22, which adjoins the specification volume 21, it is not guaranteed that the inhomogeneity in the basic field and the non-linearity of the gradient field are smaller than a specified threshold value. The specification volume 21 includes an isocenter 23 of the basic field. For imaging at a section of the object to be examined, which moves with the physiological cycle, the object is positioned in the specification volume 21 and is recorded by the primary data acquisition, which can be triggered or gated. Low-movement sections of the object to be examined can be positioned in the edge region 22 and are mapped in the waiting intervals between primary data acquisition and secondary data acquisition.

FIG. 3 illustrates the mode of operation of methods and MR systems according to example embodiments.

A physiological parameter 31 is detected as a function of time. Illustrated by way of example is an EKG signal 31. A specific feature in the time-dependent course of the physiological parameter, by way of example an R Peak 32 of the EKG-signal 31, can provoke a trigger signal. Primary data acquisition 41 occurs after a trigger delay 38 following the trigger event. Sections of the object to be examined are mapped in the process which move as a function of the physiological parameter. The first time intervals, in which the primary data acquisition 41 occurs, can be gating time slots. The first time intervals, in which primary data acquisition 41 occurs, are separated from each other by a waiting interval 40.

Primary data acquisition means that the high-movement sections of the object to be examined can each be detected in a defined movement phase. Illustrated by way of example is a movement 35 of the heart which comprises a systole 36 and a diastole 37. Primary data acquisition, which occurs so as to be synchronized with the physiological cycle, can occur in such a way that the high-movement sections of the object to be examined are subjected to primary data acquisition in the same phase of the physiological cycle respectively. Primary data acquisition, which occurs so as to be synchronized with the physiological cycle, can take place in such a way that the high-movement sections of the object to be examined are each mapped in a rest phase in which the movement speed is low.

Secondary data acquisition 42 occurs in the waiting intervals 40 between primary data acquisitions. Low-movement sections of the object to be examined, in particular the arms of the object to be examined, can be mapped using the second MR data acquired in the waiting intervals 40 during secondary data acquisition 42. Secondary data acquisition 42 only has to be coordinated with the course over time of the physiological parameter 31 to the extent that it occurs in the waiting intervals 40 and, if required, allows the execution of a transition sequence to initiate primary data acquisition 41 before the trigger delay 38 has expired. Secondary data acquisition 42 can also occur however if the sections of the object to be examined positioned in the specification volume exhibit a strong movement which is mapped by way of the monitored physiological parameter 31.

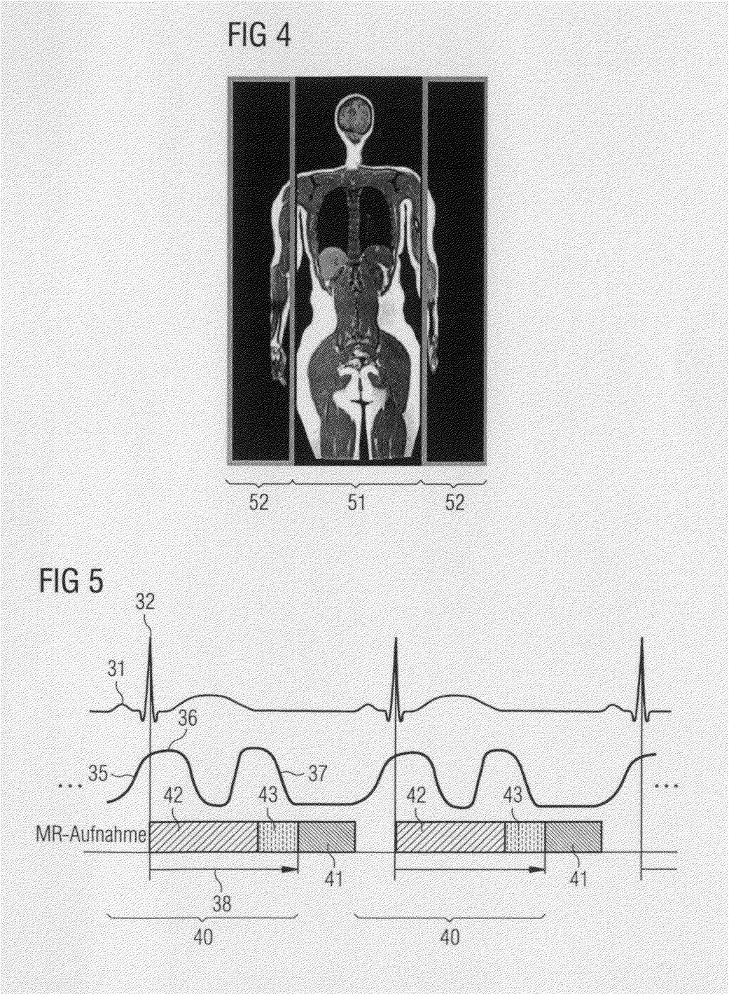

FIG. 4 illustrates an MR image of an object to be examined. First MR data 51 maps a first region of the object to be examined. The first region can be positioned in the specification volume 21 for primary data acquisition, which is carried out by way of example in gating windows or in windows defined by a trigger signal. The object to be examined can be moved relative to the MR system, so a first region of the object to be examined is moved through the specification volume 21 and can be mapped there respectively.

Second MR data 52 map a second region of the object to be examined. The second region of the object to be examined can be positioned in an edge region 22 of the field of view for secondary data acquisition, which is carried out in the waiting intervals between gating windows or in waiting intervals between the windows defined by a trigger signal.

Primary MR data acquisition and secondary MR data acquisition can be based on different MR recording techniques. By way of example acquisition 42 of the second MR data can be spin echo-based. Dephasing effects outside of the specification volume of the field of view by way of example can be effectively reduced or eliminated as a result. Acquisition 42 of the second MR data can be layer-selective. The triggered or gated acquisition 41 of the first MR data can be based on a fast gradient echo sequence. In particular a fast gradient echo sequence can be used in the state of equilibrium of transversal magnetization (by way of example an SSFP sequence) to acquire the first MR data. This allows a good use of the available rest phases for mapping the high-movement sections of the object to be examined. Acquisition 41 of the first MR data can be non-layer selective.

A transition sequence may be provided to ensure a transition between the different recording techniques. This can occur by way of example before primary data acquisition 41.

FIG. 5 illustrates MR data acquisition in methods and MR systems according to example embodiments. Data acquisition, as is illustrated in FIG. 5, can be used if primary data acquisition and secondary data acquisition are based on different recording techniques.

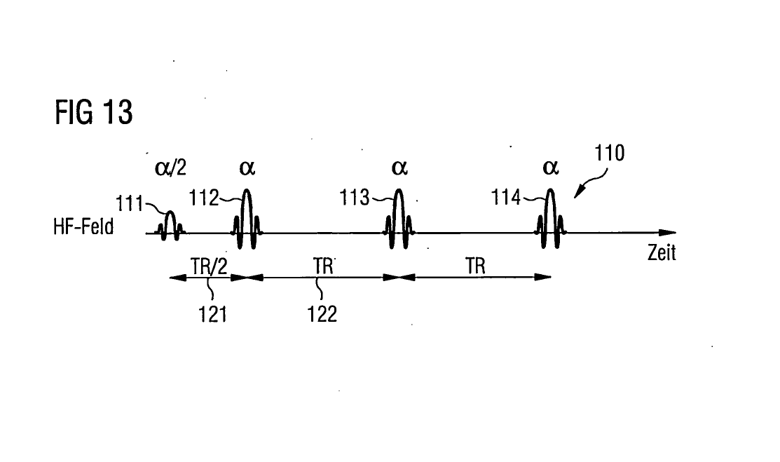

Secondary data acquisition 42 is ended before the end of the waiting interval 40. A transition sequence 43 is generated, by way of example by suitable switching of gradient fields and/or generating high frequency pulses. The transition sequence 43 is generated in such a way that it is ended by the time the trigger delay 38 has expired. The transition sequence 43 can be used to prepare a magnetization for primary data acquisition 41, by way of example if acquisition 41 of the first MR data is based on a fast gradient echo sequence in the state of equilibrium of transversal magnetization. As a transition sequence 43 a pulse sequence can in particular be used in which the magnetization has a short settling time. By way of example a pulse sequence, as is described in more detail with reference to FIG. 13, or a pulse sequence, which has pulses with rising flip angles, can be used.

In further example embodiments a layer excitation for the transition from a non-layer selective MR acquisition technique to a layer selective MR acquisition technique can be dispensed with if the secondary MR data acquisition is carried out non-selectively by an additional phase coding in the layer selection direction.

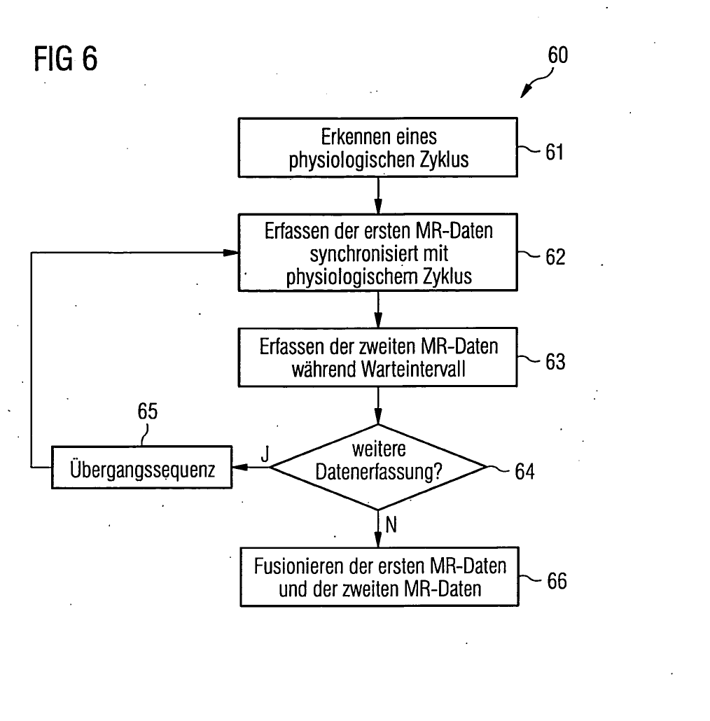

FIG. 6 is a flow diagram of a method 60 according to an example embodiment. The method 60 can be automatically carried out by an MR system according to an example embodiment. The controller 6 can undertake corresponding automatic control of the MR system.

A physiological cycle of an object to be examined is detected in step 61. For this purpose a physiological parameter, by way of example an ECG signal or breathing, can be monitored. Physiological signals can be recorded and evaluated. Alternatively or additionally, pulse techniques, what are known as navigators, can be used which repeatedly collect and evaluate information about the physiological phase during the measurement.

First MR data is acquired in step 62. The first MR data is acquired in such a way that a first region is mapped in which sections of the object to be examined are arranged which exhibit a stronger movement with the physiological parameter. The first MR data can be acquired so as to be synchronized with the physiological cycle in such a way that the first MR data is acquired in a rest phase in which the movement speed of the high-movement sections is low. The first MR data is acquired in first time intervals which can be defined by gating or trigger techniques.

In step 63 second MR data is acquired in a waiting interval between two immediately successive first time intervals. Low-movement sections of the object to be examined, by way of example the arms, are mapped in the process. The second MR data can be acquired for low-movement sections which are positioned at the edge of a field of view of the MR system. The second MR data can be acquired independently of whether the physiological cycle is currently in a rest phase.

It is checked in step 64 whether further data acquisition should occur according to the method 60. Data acquisition, in which MR data is sequentially acquired for high-movement and low-movement sections of the object to be examined in each case, can be terminated if sufficient data has been acquired either for all low-movement sections, by way of example the arms, or for all high-movement sections, by way of example the heart and organs in the thorax region. Data acquisition, in which MR data is sequentially acquired for high-movement and low-movement sections of the object to be examined in each case, can be terminated if sufficient data has been acquired either for all low-movement sections, by way of example the arms, and for all high-movement sections, by way of example the heart and organs in the thorax region. If it is determined that further data acquisition should occur according to the method 60, the method 60 returns to step 62. A transition sequence can be generated beforehand in step 65, by way of example to prepare a magnetization for acquisition of the first MR data. If it is determined in step 64 that there should be no further data acquisition using the method 60, the method continues in step 66.

In step 66 the first MR data, which was acquired in step 62, and the second MR data, which was acquired in step 63, can be merged. For this purpose the first MR data by way of example, which can map a central region of the object to be examined, and the second MR data, which can map an edge region, can be combined to form an MR image. For this purpose a first image can be reconstructed from the first MR data and a second MR image can be reconstructed from the second MR data, wherein the two reconstructed images are combined. Pixels or voxels, which correspond to high-movement tissue, can by way of example, be taken from the image which has been reconstructed from the first MR data. Pixels or voxels, which correspond to low-movement tissue, can be taken from the image which has been reconstructed from the second MR data. Alternatively or additionally, an attenuation map for a PET can be calculated from the first MR data and the second MR data.

If with the acquisition of the second MR data low-movement regions, which are arranged outside of the specification volume, are mapped in the waiting intervals, a distortion correction may be used. The image quality in edge regions of the field of view can be increased thereby as well. The distortion correction can include a correction of the acquired second MR data or the image reconstructed therefrom made by a computer. Alternatively or additionally, a distortion correction may also be used in which gradient strengths are purposefully adjusted in such a way that a destructive overlaying of the inhomogeneity in the basic field and the non-linearity of the gradient field results in each case at a certain position at the edge of the field of view, so the total distortion is reduced or completely eliminated. All techniques described in DE 10 2010 044 520 A1, the entire contents of which are incorporated herein by reference, can in particular be used for this purpose.

In addition a gradient field can be generated for acquisition of the second MR data in the waiting intervals in such a way that a distortion, which is caused by a non-linearity of the gradient field, and a distortion, which is caused by a B0 field inhomogeneity, are at least partially eliminated at a predetermined location at the edge of the field of view. The second MR data, which includes the predetermined location at the edge of the field of view, can be acquired with the aid of the gradient field generated in this way and an image of the section of the object to be examined at the predetermined location can be determined from the second MR data.

The gradient G of the gradient field can be determined according to the following equation

G=−δB₀(x,y,z)/c(x,y,z) (1)

where δB₀ is the B₀ field inhomogeneity at the predetermined location with coordinates (x,y,z) at the edge of the field of view and c is the relative gradient error at the predetermined location (x,y,z). Once the MR system has been measured, i.e. the relative gradient error and the B₀ field inhomogeneity for certain locations or regions, by way of example regions in which the arms of the patient are likely to be located, have been determined, gradients of the gradient field can therefore be easily determined and generated to reliably be able to determine an image of the object to be examined at the predetermined location, i.e. without distortion, or with only slight distortion.

Alternatively or additionally, the B0 field inhomogeneity can be determined at the predetermined location at the edge of the field of view to generate the gradient field, and a gradient coil for generating the gradient field can be configured in such a way that a non-linearity of the gradient field and the B0 field inhomogeneity are cancelled out at the predetermined location. Since, by way of example for a PET attenuation correction, conventionally only some regions at the edge of the field of view of the MR system have to be acquired so as to be free from distortion, by way of example regions in which the arms of the object to be examined are likely to be located, a gradient coil can be optimized such that the non-linearity of the gradient field generated by the gradient coil substantially cancels outs the B0 field inhomogeneity in these regions in the case of a predetermined gradient field.

Alternatively or additionally, for generating the gradient field the non-linearity of the gradient field at the predetermined location at the edge of the field of view can be determined and the B0 field changed in such a way that the non-linearity of the gradient field and the B0 field inhomogeneity are cancelled out at the predetermined location. The change in the B0 field can be adjusted by way of example by suitable arrangement of what are known as shim sheets. Consequently low, or even no, distortion can be achieved at least for some predetermined regions, by way of example regions in which the arms of the object to be examined are expected to lie.

Any of the techniques described above can be used by way of example if a distortion correction is made for acquisition of the second MR data outside of the specification volume. Corresponding data acquisition during the waiting intervals between two rest phases can be performed to map by way of example arms of the object to be examined so as to be free of distortion or with reduced distortion. This data acquisition is combined with triggered or gated data acquisition for the specification volume.

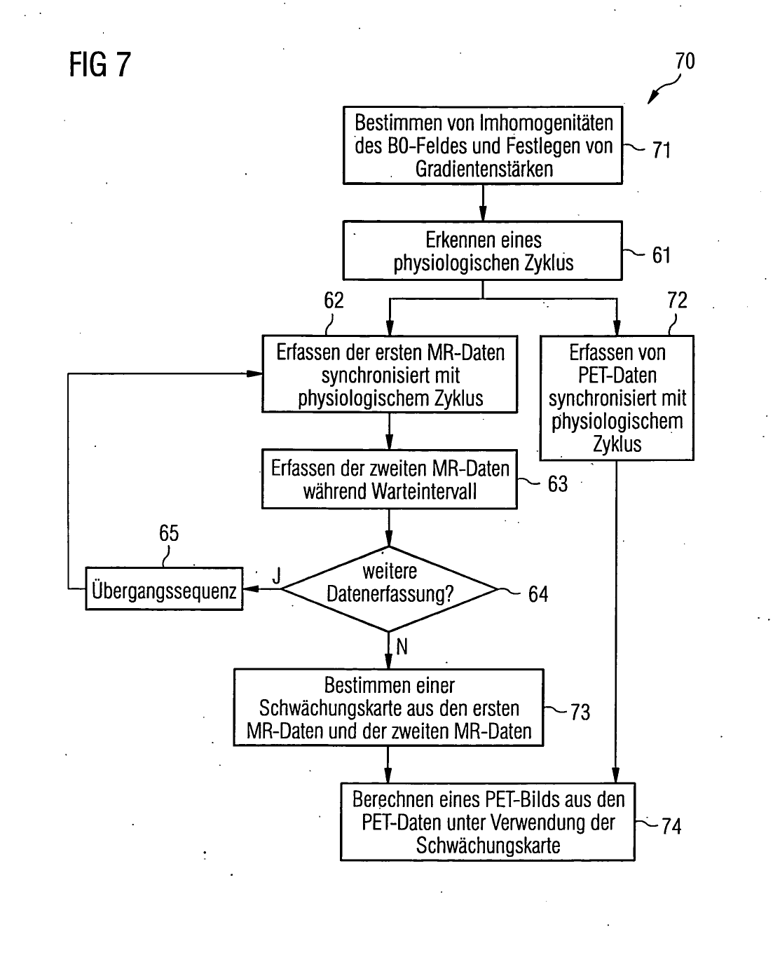

FIG. 7 is a flow diagram of a method 70 which can be carried out using an MR-PET hybrid system. The method 70 can in particular be automatically carried out by the MR-PET hybrid system 1. Steps of the method 70, which can be carried out as explained below with reference to FIG. 6, are designated by the same reference numerals.

In step 71 the inhomogeneity in the basic field is determined. The inhomogeneity can be acquired by measuring the tomograph 2 and can then be stored for a plurality of MR data acquisitions in a memory of the controller 6. Gradient strengths are defined. This may occur by way of example in accordance with equation (1). The gradient strengths can be determined for which the distortion is reduced or completely eliminated at those parts of the edge region of the field of view in which the arms are positioned.

The physiological cycle is detected in step 61.

PET data can be acquired in step 72 parallel with the acquisition of MR data in steps 62-65. The PET data may also be acquired in a manner coordinated with the physiological cycle. This applies in particular, if by way of example PET data is to be acquired for a tumor in an organ. The PET data can be acquired during the rest phases of the physiological cycle and therefore parallel with the acquisition of the first MR data in step 62.

In step 73 an attenuation map can be determined from the first MR data and the second MR data for the photoemission of the PET. For this purpose the first MR data and the second MR data can be combined by way of example as described with reference to FIG. 6 to form an MR image. Different types of tissue can be identified by segmenting the MR image. The attenuation map can be calculated using a characteristic diagram, which stores the absorption coefficients for the photons emitted during the PET for different types of tissue.

In step 74 a PET image is determined from the PET data acquired in step 73 and the attenuation map determined in step 73 is established.

whereas a distortion correction is used in the method 70 in the case of acquisition of the second MR data for an MR-PET hybrid system, the method can accordingly also be used in an MR system which is not configured to carry out PET.

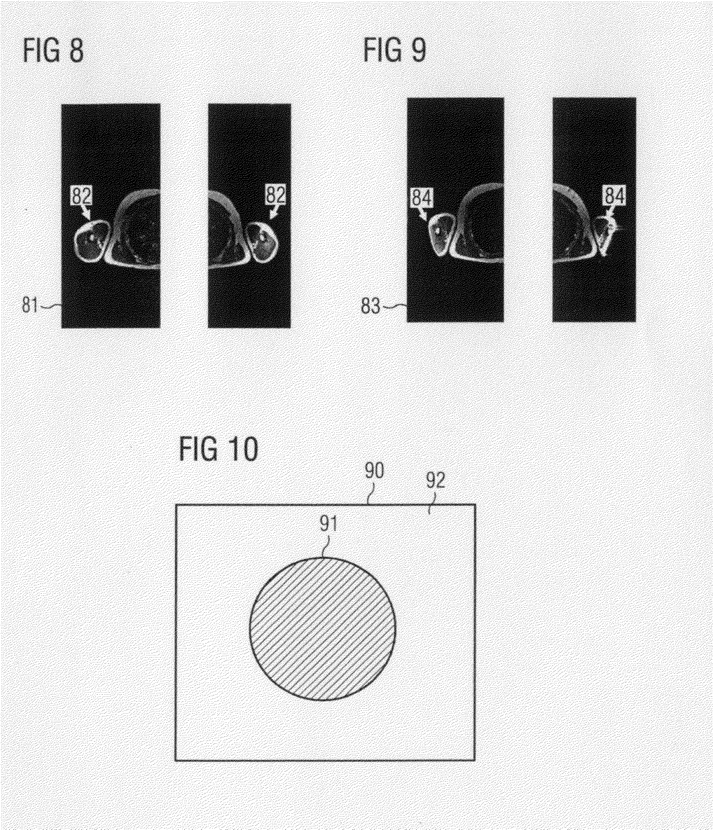

FIG. 8 illustrates MR imaging using methods and MR systems according to example embodiments, in which acquisition of the second MR data in the edge region of the field of view using a distortion correction is combined with a gated or triggered MR data acquisition for the specification volume.

FIG. 8 shows an MR image 81 which has been generated using such a method according to an example embodiment. A distortion correction according to equation (1) has been used here. The arms of the object to be examined are mapped at 82 so as to be substantially free from distortion.

FIG. 9 shows by way of comparison an MR image 83 in which the arms are likewise arranged in an edge region of the field of view, but a distortion correction has been omitted. The arms of the object to be examined are mapped at 84 and exhibit significant distortions.

FIG. 10 illustrates the combination of first MR data, which is selectively acquired only during the rest phases of the physiological cycle and maps a first region, and second MR data, which maps a second region with low-movement sections of the object to be examined and is acquired during the waiting intervals between rest phases of the physiological cycle.

Voxels or pixels 91 of the combined data record 90, which during data acquisition are arranged by way of example in the specification volume of the MR system, can be filled based on the image reconstructed from the first MR data. Voxels or pixels, which are reconstructed from the first MR data acquired during primary data acquisition for an edge region outside of the specification volume, can be discarded.

Voxels or pixels 92 of the combined data record 90, which during data acquisition are arranged by way of example in the edge region outside of the specification volume, can be filled based on the image reconstructed from the second MR data. Voxels or pixels, which are reconstructed from second MR data, acquired during secondary data acquisition, for the specification volume, can be discarded.

The combined data record 90 can by way of example be an MR image or an attenuation map.

To achieve fast secondary MR data acquisition in the waiting intervals between the rest phases of the physiological cycle, in which the primary MR data is acquired, in methods and MR systems according to example embodiments a distortion correction during acquisition of the second MR data, as has been explained by way of example with reference to equation (1), can be combined with further techniques.

By way of example, a multi-layer spin echo sequence can be used for the acquisition of the second MR data. For this purpose the layer position-dependent defining of a read gradient strength, by way of example according to equation (1), can be expanded to a gradient array. A desired number of layers and desired layer positions can be fixed so as to be defined by a user. An array is automatically generated which contains the corresponding gradient strengths which are separately determined for each layer position. The gradient amplitude or gradient strength can be determined by way of example according to equation (1) in each case. A multi-layerspin echo sequence using the calculated gradient arrays leads to simultaneous scanning of distortion-reduced layers and therefore to a reduction in measuring time. A multi-layer-spin echo sequence of this kind for mapping the arms of the object to be examined is interlaced with gated or triggered scanning of the higher-movement sections of the object to be examined.

A distortion correction, as has been described by way of example with reference to equation (1), can also be combined with what is known as a “dual echo” spin echo sequence. Here the gradient strengths can be respectively calculated according to equation (1) for the positions of the two arms, wherein this can involve by way of example the strength of a first read gradient and a second read gradient. A first spin echo can be acquired using the first read gradient and a second spin echo can be acquired using the second read gradient. The first arm can be reconstructed from the first spin echo so as to be distortion-corrected. The second arm can be reconstructed from the second spin echo so as to be distortion-corrected. A “dual echo” spin echo sequence of this kind for mapping the arms of the object to be examined is interlaced with gated or triggered scanning of the higher-movement sections of the object to be examined.

In general, to carry out the “dual echo” spin echo sequence a first read gradient field can be determined in such a way that at a predetermined first location of the field of view of the MR system a distortion caused by a non-linearity of the first read gradient field and a distortion caused by a B0 field inhomogeneity are substantially cancelled out. A second read gradient field can be determined in such a way that at a predetermined second location of the field of view, which is different to the first location, a distortion caused by a non-linearity of the second read gradient field and a distortion caused by a B0 field inhomogeneity are substantially cancelled out. A multi-echo sequence can be carried out, wherein after a 180° pulse, MR data of a first spin echo is acquired using the first read gradient field and after a further 180° pulse, MR data of a second spin echo is acquired using the second read gradient field.

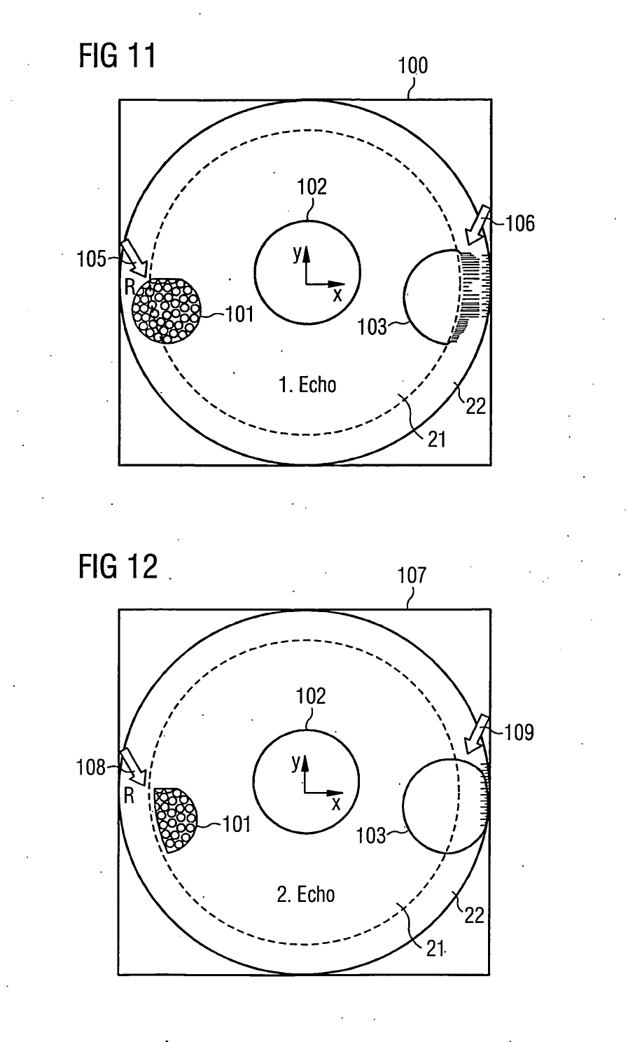

FIG. 11 and FIG. 12 illustrate a method of this kind. The tomograph 2 has an internal diameter of by way of example 600 mm, while the specification volume 21 is smaller and can have a diameter by way of example of 500 mm. Imaging arranged at three phantom objects 101, 102, 103 is illustrated. The phantom object 102 is arranged in the isocenter of the magnetic resonance system 1. The phantom object 101 is located in the negative x direction at the inner edge of the tomograph 2. The phantom object 103 is located in the positive x direction at the inner edge of the tomograph 2.

FIG. 11 shows an MR image 100 of the three phantom objects 101-103 on the basis of the MR data which was acquired with the first echo and the first read gradient field. The phantom object 102 in the center of the field of view, which by way of example is detected with gated or triggered data acquisition, has been acquired so as to be free from distortion. Since the first read gradient field was optimized for a location in the edge region in the negative x direction, the phantom object 101 is illustrated with relatively low distortions. In particular in the region 105 outside of the specification volume 21, denoted by the arrow, the structure of the phantom object 101 is only slightly distorted. The phantom object 103, on the other hand, is highly distorted in the region 22 outside of the specification volume 21, as is illustrated by the arrow at 106.

FIG. 12 shows an MR image 107 which was determined on the basis of the MR data which was acquired with the second echo and the second read gradient field. When acquiring this MR data a read gradient field was applied which was optimized for a location in the positive x direction. The phantom object 103 is accordingly only relatively slightly distorted, in particular in the edge region 109 denoted by the arrow. The phantom object 101, on the other hand, is highly distorted in the region 108 denoted by the arrow.

By combining the MR images 100, 107 and the MR image for the specification volume, determined by gated or triggered data acquisition, a high-quality image can be produced overall. For this purpose pixels or voxels in the edge region 22 of the field of view are taken from those in the MR images 100, 107 in which the read gradient field at the corresponding pixels or voxels is chosen according to equation (1) and leads to a slight distortion.

A distortion correction, as has been described by way of example with reference to equation (1), can also be combined with a continuous movement of the examination table 3. For this purpose a gradient strength of a read gradient field can be calculated and applied in a freely selectable layer position. The calculation can be made by way of example based on equation (1). The measurement object is moved through this optimized layer position by what is known as a “continuously moving table” technique.

In example embodiments of the invention acquisition of the first MR data, which can be undertaken as gated or triggered MR data acquisition, and the acquisition of the second MR data, with which low-movement sections of the object to be examined can be mapped, occur with different MR recording techniques. By way of example, first MR data can be acquired with a non-layer-selective gradient echo sequence. To prepare the layer magnetization a transition sequence can be generated, as has already been explained with reference to FIG. 5 and FIG. 6.

The transition sequence can be chosen such that a short settling time of magnetization is attained. The period in which the second MR data can in each case be acquired can consequently be extended. In one embodiment a pulse sequence can be used in the state of equilibrium for preparation of the magnetization, and this accelerates the settling process. FIG. 13 illustrates a pulse sequence of this kind.

FIG. 13 shows a sequence 110 of high frequency pulses, as may be used for preparation of the magnetization for acquisition of the first MR data. A plurality of high frequency pulses is generated to achieve a certain flip angle of the spin in each case. Gradient fields (not shown in FIG. 13) are switched in the process. In a deviation from a conventional sequence for the transition into a state of equilibrium of the transversal magnetization not all high frequency pulses correspond to the same size of flip angle. A first high frequency pulse 111 is generated which can correspond to a flip angle of α/2. According to a first period 121 a second high frequency pulse 112 is generated which can correspond to a flip angle of a size α, i.e. a flip angle which is twice as large as the first high frequency pulse 111. After a second period 122 further high frequency pulses 113, 114 are generated respectively which can correspond to a flip angle of the same size α as the second high frequency pulse 112. The first period 121 can be half the repetition rate TR, after which one new high frequency pulse respectively is generated as of the second high frequency pulse 112. The MR system can be controlled in such a way that the sign of the flip angles alternate. Settling processes can be shorted using such a pulse sequence.

Other transition sequences can be used. By way of example a pulse sequence can be used in which the high frequency pulses correspond to linearly increasing flip angles.

while example embodiments have been described in detail with reference to figures, modifications may be implemented in further example embodiments. While, by way of example, the interlacing of gated or triggered MR data acquisition with second MR data acquisition, which maps the arms of an object to be examined, has been described, the methods and devices can also be used to map other low-movement sections of an object to be examined between the rest phases a physiological cycle. While the use of methods and devices according to example embodiments for determining an attenuation map for PET have been described, the example embodiments are not limited to such applications.

Although the invention has been illustrated and described in more detail by preferred example embodiments, it is not restricted by the disclosed example embodiments and the person skilled in the art may derive other variations herefrom without departing from the scope of the invention.

What is claimed is:

1. A magnetic resonance (MR) tomography method, comprising:
acquiring a physiological parameter of an object to be examined as a function of time to detect a physiological cycle which repeats itself over time;
acquiring first MR data for a first region, wherein all points of the first region are arranged in a region of a field of view of an MR system, wherein acquisition of the first MR data occurs selectively in first time intervals synchronized with a physiological cycle and separated from each other by waiting intervals; and
acquiring second MR data for a second region, different from the first region, wherein acquisition of the second MR data occurs in the waiting intervals between the first time intervals.

2. The method of claim 1, comprising:
adjusting a relative position between the object to be examined and the MR system such that sections of the object to be examined, which move in a coordinated manner with the physiological cycle, are arranged in the first region.

3. The method of claim 1, wherein the second MR data maps low movement sections of the object to be examined.

4. The method of claim 1, wherein acquisition of the second MR data comprises:
adjusting a gradient strength of at least one gradient field as a function of an inhomogeneity in a B0 field and a non-linearity of the gradient field of the MR system to reduce a distortion.

5. The method of claim 1, wherein the method is performed using an MR-positron-emission tomography (PET) hybrid system, and wherein the method further comprises:
determining an attenuation map for a PET image based on the first MR data and the second MR data.

6. The method of claim 5, wherein determination of the attenuation map comprises:
determining an absorption parameter for a plurality of voxels arranged in the first region, based on the first MR data, and
determining the absorption parameter for a further plurality of voxels, arranged in the second region, based on the second MR data.

7. The method of claim 1, wherein acquisition of the first MR data is carried out using a first MR acquisition technique, and wherein acquisition of the second MR data is carried out using a second MR acquisition technique, different from the first MR acquisition technique.

8. The method of claim 7, wherein the second MR acquisition technique is an MR acquisition technique which allows compensation of dephasing effects.

9. The method of claim 7, wherein the first MR acquisition technique comprises:
generating a gradient echo sequence, and
wherein the second MR acquisition technique comprises:
generating a spin echo sequence.

10. The method of claim 7, further comprising:
generating a transition sequence in coordination with the physiological cycle to prepare the object to be examined for acquisition of the first MR data using the first MR acquisition technique.

11. The method of claim 7, wherein the first acquisition technique is non-layer-selective, and wherein the second acquisition technique is layer-selective.

12. The method of claim 7, wherein the second region is arranged at an edge of the field of view of the MR system.

13. The method of claim 1, wherein the second MR data is acquired in second time intervals respectively which are contained in the waiting intervals, and wherein a duration of the second time intervals is chosen as a function of a duration of the physiological cycle.

14. The method of claim 1, wherein the physiological cycle is a cardiac cycle or a breathing cycle.

15. A magnetic resonance (MR) system, comprising:
a device configured to generate a basic field;
an acquisition device configured to acquire MR data; and
a controller configured to control the MR system, wherein the controller comprises an interface configured to receive a signal which depends on a physiological parameter of an object to be examined, wherein the controller is further configured
to detect a physiological cycle which repeats itself over time as a function of the signal received at the interface,
to control the acquisition device to acquire first MR data for a first region, wherein all points of the first region are arranged in a region of field of view of the MR system,
to control the acquisition device in such a way that acquisition of the first MR data occurs selectively in first time intervals which are synchronized with the physiological cycle and which are separated from each other by waiting intervals, and
to control the acquisition device to acquire second MR data for a second region, different from the first region, in such a way that acquisition of the second MR data occurs in the waiting intervals between the first time intervals.

16. The MR system of claim 15, configured to carry out the method of claim 1.

17. A magnetic resonance (MR)—positron-emission tomography (PET) hybrid system, comprising:
the MR system of claim 15; and
a positron-emission tomograph, comprising:
a detector configured to acquire PET data, and
a processing device, coupled to the MR system and set up to determine an attenuation map for the PET data as a function of the first MR data and second MR data acquired with the MR system.

18. The method of claim 8, wherein the first MR acquisition technique comprises:
generating a gradient echo sequence, and
wherein the second MR acquisition technique comprises:
generating a spin echo sequence.

19. A magnetic resonance (MR)—positron-emission tomography (PET) hybrid system, comprising:
the MR system of claim 16; and
a positron-emission tomograph, comprising:
a detector configured to acquire PET data, and
a processing device, coupled to the MR system and set up to determine an attenuation map for the PET data as a function of the first MR data and second MR data acquired with the MR system.
